(19) United States
(12) Patent Application Publication
(10) Pub. No.: US 2010/0176463 A1
(43) Pub. Date: Jul. 15, 2010

(54) SEMICONDUCTOR DEVICE AND MANUFACTURING METHOD OF THE SAME

(75) Inventors: Koshiro KOIZUMI, Tokyo (JP); Hitoshi SESHIMO, Tokyo (JP); Hideo KINOSHITA, Tokyo (JP)

Correspondence Address: MATTINGLY & MALUR, P.C., 1800 DIAGONAL ROAD, SUITE 370, ALEXANDRIA, VA, 22314, US

(73) Assignee: RENESAS TECHNOLOGY CORP., Tokyo (JP)

(21) Appl. No.: 12/663,737

(22) PCT Filed: May 20, 2008
(86) PCT No.: PCT/JP2008/059221

§ 371 Date: Dec. 9, 2009

(30) Foreign Application Priority Data
Jul. 19, 2007 (JP) 2007-188083

(51) Int. Cl. H01L 29/66; H01L 21/30

(52) U.S. Cl. 257/414; 438/49; 257/E29.166; 257/E21.211

(57) ABSTRACT

In order to provide a technique capable of executing an etching process using a dry etching method and a wet etching method in combination with high processing dimensional accuracy, an interlayer insulating film 13, an etching stopper film 14, interlayer insulating films 15 and 18 and a surface protection film 19 are sequentially deposited on a sensor film 12. As the etching stopper film 14, a material different in etching selectivity from the interlayer insulating films 13, 15 and 18 is selected. Next, the surface protection film 19 and the interlayer insulating films 18 and 15 are sequentially dry-etched with using the etching stopper film 14 as an etching stopper, and subsequently, the etching stopper film 14 is dry-etched with using the interlayer insulating film 13 as an etching stopper. Thereafter, the interlayer insulating film 13 is wet-etched with using the sensor film 12 as an etching stopper.

### TECHNICAL FIELD

The present invention relates to a semiconductor device and a manufacturing technique thereof, and in particular, it relates to a technique effectively applied to a semiconductor device processed by an etching process using a dry etching method and a wet etching method in combination and a manufacturing technique thereof.

### BACKGROUND ART

Japanese Patent Application Laid-Open Publication No. 2002-131276 (Patent Document 1) discloses a technique in which a chemical image sensor cell is formed by using an optical address potential response sensor, thereby realizing a convenient inexpensive chemical image sensor capable of reducing an environmental burden.

Japanese Patent Application Laid-Open Publication No. 2002-181773 (Patent Document 2) discloses a technique in which, in a chemical sensor obtained by providing a sensitive portion, a reference electrode and a counter electrode of the sensor on a gate film of a MOS type device provided on a semiconductor substrate and covering the portion and the electrodes with an electrolytic material, a chemical image sensor is formed by using a surface photovoltage method utilizing rear-surface irradiation, thereby realizing high-speed processing of chemical image signals, miniaturization of the device, and an inexpensive chemical image sensor.

Japanese Patent Application Laid-Open Publication No. 2001-272372 (Patent Document 3) discloses a field effect transistor which is provided with a channel having a diamond hydrogen terminal surface exposed between a gate electrode and a drain electrode and a gate made of a liquid electrolyte filling the exposed diamond hydrogen terminal surface of the channel and stably operates in the liquid electrolyte.

WO2003/042683 (Patent Document 4) discloses a FET (Field Effect Transistor) type sensor, an ionic concentration detection method and a base sequence detection method using the sensor.

[Patent Document 1] Japanese Patent Application Laid-Open Publication No. 2002-131276

[Patent Document 2] Japanese Patent Application Laid-Open Publication No. 2002-181773

[Patent Document 3] Japanese Patent Application Laid-Open Publication No. 2001-272372

[Patent Document 4] WO2003/042683

### DISCLOSURE OF THE INVENTION

### Problem to be Solved by the Invention

The present inventors have been studying the manufacturing technique of a pH image sensor based on MEMS (Micro Electro Mechanical Systems). During the study, the present inventors have found following problems.

That is, the sensor portion of the pH image sensor based on the MEMS studied by the present inventors has a structure in which a thin sensor film (SiN film) is provided on a MISFET (Metal Insulator Semiconductor Field Effect Transistor) via a thin oxide film, and the pH is calculated by an adsorption density of H (hydrogen) ion to this SiN film serving as the sensor film. Because of such a principle of use, the SiN film as the sensor film must be exposed, and an opening reaching an interlayer insulating film and a surface protection film on the sensor film needs to be formed. If the sensor film is exposed to a dry etching atmosphere when such an opening is formed, an H ion adsorption ability of the sensor film is reduced, and therefore, in the vicinity of the sensor film surface, the opening must be formed by wet etching.

The dry etching is anisotropic etching, whereas the wet etching is isotropic etching. Therefore, if an attempt is made to form the opening only by the wet etching when the interlayer insulating film on the sensor film becomes thick, a side etching amount also increases. Hence, there is a fear of causing a trouble that a diameter of the opening becomes extremely larger than the desired diameter. Consequently, a processing method is considered in which a processing proceeds by the dry etching until immediately before the sensor film, and only the last process of exposing the surface of the sensor film is performed by the wet etching.

However, when the miniaturization of the MISFET and processing dimensions of a wiring and the like electrically connected to the MISFET proceeds in order to improve sensor density, the diameter of the opening also becomes small, and a side etching amount by the wet etching significantly affects the processing dimensions of the opening. More specifically, when the dry etching is stopped at a safe point not reaching the sensor film and the remaining part is processed by a wet-type over etching, the film thickness to be wet-etched becomes large, and this causes a trouble that the side etching amount becomes large and the opening cannot be miniaturized.

Further, for the purpose of miniaturizing the opening described above, a processing method in which the dry etching is performed until immediately before the sensor film and the remaining part is processed by the wet etching is considered. However, since the dry etching is performed until immediately before the sensor film, the sensor film is exposed to a dry etching atmosphere, and there is a fear of causing a trouble that the H ion adsorption ability of the sensor film is reduced.

Further, in the case of a structure in which the pH image sensor has a wiring and the like provided in a multilayer manner, the shape of the difference in level appears complicatedly, so that the film thickness of the interlayer insulating film also becomes large and non-uniform. Therefore, a control of the dry etching and the wet etching in consideration of the difference in film thicknesses of the interlayer insulating film caused by the difference in level becomes almost impossible. Further, when the thickness of the interlayer insulating film on the sensor portion (sensor film) is to be uniformized by removing the difference in level, the restriction of a wiring layout and the like near the sensor portion becomes large and the layout cannot be freely designed. Further, since the side etching amount fluctuates due to the difference in level depending on the processing spots and a short-circuit failure and the like due to the etching residue, the over-etching and the like are caused, there is a fear of reducing a yield of the pH image sensor.

Incidentally, when the film thickness of the interlayer insulating film on the sensor film becomes large and the diameter of the opening reaching the sensor film becomes small, the influence of the attachment of the polymer generated as a by-product material at the dry etching of the interlayer insulating film to the side wall of the opening is also increased. More specifically, since this polymer is hard to be removed by the wet etching, the etching residue by the polymer remains inside the opening, and there is a fear of causing a trouble that the processing itself of the opening cannot be performed.

An object of the present invention is to provide a technique capable of performing an etching process using the dry etching method and the wet etching method in combination with high processing dimensional accuracy.

The above and other objects and novel characteristics of the present invention will be apparent from the description of this specification and the accompanying drawings.

### Means for Solving the Problems

The typical ones of the inventions disclosed in this application will be briefly described as follows.

(1) A semiconductor device according to the present invention comprises:

a sensor element formed on a main surface of a semiconductor substrate;

a first thin film formed on the main surface of the semiconductor substrate on which the sensor element has been formed;

a first insulating film formed on the main surface of the semiconductor substrate including the first thin film;

a second insulating film formed on the first insulating film;

a second thin film patterned between the first insulating film and the second insulating film on a first region of the main surface of the semiconductor substrate, and having etching selectivity to the first insulating film and the second insulating film; and

an opening formed in the first insulating film, the second insulating film and the second thin film, and reaching the first thin film,

wherein the sensor element is provided with a first electrode patterned on the main surface of the semiconductor substrate, and detects a material to be measured reaching the semiconductor substrate through the opening,

the first thin film covers an upper surface and a side surface of the first electrode, a bottom of the opening, and at least a part of a side surface of the opening,

the second thin film covers an upper surface of the first electrode,

a surface of the first thin film at the bottom of the opening and at least the part of the side surface of the opening is exposed, and

the first thin film is a thin film electrically operating the sensor element by the material to be measured.

(2) Also, a semiconductor device according to the present invention comprises:

a sensor element formed on a main surface of a semiconductor substrate;

a first thin film formed on the main surface of the semiconductor substrate on which the sensor element has been formed;

a first insulating film formed on the main surface of the semiconductor substrate including the first thin film;

a second insulating film formed on the first insulating film;

a third thin film patterned with a first pattern between the first insulating film and the second insulating film on a first region of the main surface of the semiconductor substrate, and having etching selectivity to the first insulating film and the second insulating film; and

an opening formed in the first insulating film and the second insulating film, and reaching the first thin film,

wherein the sensor element is provided with a first electrode patterned on the main surface of the semiconductor substrate, and detects a material to be measured reaching the semiconductor substrate through the opening,

the first thin film covers an upper surface and a side surface of the first electrode, a bottom of the opening and at least a part of a side surface of the opening,

a surface of the first thin film at the bottom of the opening and at least the part of the side surface of the opening is exposed, and

the first thin film is a thin film electrically operating the sensor element by the material to be measured.

(3) Also, a manufacturing method of a semiconductor device according to the present invention comprises the steps of:

(a) forming a sensor element on a main surface of a semiconductor substrate;

(b) forming a first thin film on the main surface of the semiconductor substrate under a presence of the sensor element;

(c) forming a first insulating film on the main surface of the semiconductor substrate including the first thin film;

(d) forming a second thin film having etching selectivity to the first insulating film on the first insulating film, and patterning the second thin film on a first region of the main surface of the semiconductor substrate;

(e) forming a second insulating film having etching selectivity to the second thin film on the first insulating film including the second thin film;

(f) forming a first masking layer on the second insulating film and anisotropically dry etching the second insulating film on the first region by a first planer shape with using the first masking layer as a mask, thereby forming an opening reaching the second thin film;

(g) anisotropically dry etching the second thin film below the opening by the first planer shape with using the first masking layer as a mask, thereby expanding the opening so as to reach the first insulating film; and

(h) after the step (g), isotropically wet etching the first insulating film below the opening, thereby expanding the opening so as to reach the first thing film.

(4) Also, a manufacturing method of a semiconductor device according to the present invention comprises the steps of:

(a) forming a first sensor element and a second sensor element on a main surface of a semiconductor substrate;

(b) forming a first thin film on the main surface of the semiconductor substrate under a presence of the first sensor element and the second sensor element;

(c) forming a first insulating film on the main surface of the semiconductor substrate including the first thin film,

(d) forming a second thin film having etching selectivity to the first insulating film on the first insulating film, and patterning the second thin film on a first region and a second region of the main surface of the semiconductor substrate,

(e) forming a second insulating film on the first insulating film including the second thin film, the second insulating film having etching selectivity to the second thin film and different film thicknesses on the first region and the second region;

(f) forming a first masking layer on the second insulating film and anisotropically dry etching the second insulating films on the first region and the second region respectively by a first planer shape with using the first masking layer as a mask, thereby forming openings reaching the second thin film in the first region and the second region, respectively;

(g) anisotropically dry etching the second thin film below the opening by the first planer shape with using the first masking layer as a mask, thereby expanding the opening so as to reach the first insulating film; and

(h) after the step (g), isotropically wet etching the first insulating film below the opening, thereby expanding the opening so as to reach the first thin film.

(5) Also, a manufacturing method of a semiconductor device according to the present invention comprises the steps of:

(a) forming a sensor element on a main surface of a semiconductor substrate;

(b) forming a first thin film on the main surface of the semiconductor substrate under a presence of the sensor element;

(c) forming a first insulating film on the main surface of the semiconductor substrate including the first thin film;

(d) forming a third thin film having etching selectivity to the first insulating film on the first insulating film, and patterning the third thin film on a first region of the main surface of the semiconductor substrate by a first pattern;

(e) forming a second thin film having etching selectivity to the first insulating film on the first insulating film including the third thin film, and patterning the second thin film on the first region;

(f) forming a second insulating film having etching selectivity to the second thin film on the first insulating film including the second thin film;

(g) forming a first masking layer on the second insulating film and anisotropically dry etching the second insulating film on the first region by a first planer shape with using the first masking layer as a mask, thereby forming an opening reaching the second thin film;

(h) anisotropically dry etching the second thin film below the opening by the first planer shape with using the first masking layer as a mask, thereby expanding the opening; and

(i) after the step (h), isotropically wet etching the first insulating film below the opening, thereby expanding the opening so as to reach the first thin film.

### EFFECT OF THE INVENTION

The effects obtained by typical embodiments of the inventions disclosed in this application will be briefly described below.

According to the present invention, an etching process using the dry etching method and the wet etching method in combination can be performed with high processing dimensional accuracy.

### BRIEF DESCRIPTION OF THE DRAWINGS

FIG. 1 is a cross-sectional view of the principal part for describing the manufacturing method of a semiconductor device according to a first embodiment of the present invention;

FIG. 2 is a cross-sectional view of the principal part in the manufacturing process of the semiconductor device continued from FIG. 1;

FIG. 3 is a cross-sectional view of the principal part in the manufacturing process of the semiconductor device continued from FIG. 2;

FIG. 4 is a cross-sectional view of the principal part in the manufacturing process of the semiconductor device continued from FIG. 3;

FIG. 5 is a cross-sectional view of the principal part in the manufacturing process of the semiconductor device continued from FIG. 4;

FIG. 6 is a plan view of the principal part in the manufacturing process of the semiconductor device according to the first embodiment of the present invention;

FIG. 7 is a cross-sectional view of the principal part in the manufacturing process of the semiconductor device continued from FIG. 5;

FIG. 8 is a cross-sectional view of the principal part in the manufacturing process of the semiconductor device continued from FIG. 7;

FIG. 9 is a plan view of the principal part in the manufacturing process of the semiconductor device according to the first embodiment of the present invention;

FIG. 10 is an explanatory diagram showing an operation principle of a pH image sensor as the semiconductor device according to the first embodiment of the present invention;

FIG. 11 is a cross-sectional view of the principal part in the manufacturing process of a semiconductor device compared with the manufacturing method of the semiconductor device according to the first embodiment of the present invention;

FIG. 12 is a cross-sectional view of the principal part in the manufacturing process of the semiconductor device continued from FIG. 11;

FIG. 13 is a cross-sectional view of the principal part in the manufacturing process of a semiconductor device compared with the manufacturing method of the semiconductor device according to the first embodiment of the present invention;

FIG. 14 is an explanatory diagram showing the malfunction of the pH image sensor;

FIG. 15 is a plan view of the principal part of the semiconductor device according to the first embodiment of the present invention;

FIG. 16 is a cross-sectional view of the principal part for describing the manufacturing method of a semiconductor device according to a second embodiment of the present invention;

FIG. 17 is a cross-sectional view of the principal part in the manufacturing process of the semiconductor device continued from FIG. 16;

FIG. 18 is a cross-sectional view of the principal part in the manufacturing process of the semiconductor device continued from FIG. 17;

FIG. 19 is a cross-sectional view of the principal part in the manufacturing process of the semiconductor device continued from FIG. 18;

FIG. 20 is a cross-sectional view of the principal part in the manufacturing process of the semiconductor device continued from FIG. 19;

FIG. 21 is a cross-sectional view of the principal part in the manufacturing process of a semiconductor device compared with the manufacturing method of the semiconductor device according to the second embodiment of the present invention;

FIG. 22 is a plan view of the principal part in the manufacturing process of a semiconductor device according to a third embodiment of the present invention;

FIG. 23 is a plan view of the principal part in the manufacturing process of the semiconductor device continued from FIG. 22;

FIG. 24 is a plan view of the principal part in the manufacturing process of a semiconductor device compared with the manufacturing method of the semiconductor device according to the third embodiment of the present invention;

FIG. 25 is a cross-sectional view of the principal part in the manufacturing process of a semiconductor device according to a fourth embodiment of the present invention;

FIG. 26 is a plan view of the principal part in the manufacturing process of the semiconductor device according to the fourth embodiment of the present invention;

FIG. 27 is a cross-sectional view of the principal part in the manufacturing process of a semiconductor device according to a fifth embodiment of the present invention;

FIG. 28 is a plan view of the principal part in the manufacturing process of the semiconductor device according to the fifth embodiment of the present invention;

FIG. 29 is a plan view of the principal part in the manufacturing process of the semiconductor device according to the fifth embodiment of the present invention; and

FIG. 30 is a plan view of the principal part in the manufacturing process of the semiconductor device according to the fifth embodiment of the present invention.

### BEST MODE FOR CARRYING OUT THE INVENTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of elements (including number of pieces, values, amount, range, and the like), the number of the elements is not limited to a specific number unless otherwise stated or except the case where the number is apparently limited to a specific number in principle, and the number larger or smaller than the specified number is also applicable.

Further, in the embodiments described below, it goes without saying that the components (including element steps) are not always indispensable unless otherwise stated or except the case where the components are apparently indispensable in principle. Also, even when mentioning that constituent elements or the like are “made of A” or “comprise A” in the embodiments below, elements other than A are not excluded except the case where it is particularly specified that A is the only element thereof.

Similarly, in the embodiments described below, when the shape of the components, positional relation thereof, and the like are mentioned, the substantially approximate and similar shapes and the like are included therein unless otherwise stated or except the case where it can be conceived that they are apparently excluded in principle. The same goes for the numerical value and the range described above.

Still further, when the materials and the like are mentioned, the specified material is a main material unless otherwise stated or except the case where it is not so in principle or situationally, and the secondary components, additives, additional components and the like are not excluded. For example, a silicon material includes not only the case of pure silicon but also secondary and ternary alloys (for example, SiGe) and the like formed of additive impurities and silicon as the main component unless otherwise stated.

Also, components having the same function are denoted by the same reference symbols throughout the drawings for describing the embodiments, and the repetitive description thereof is omitted.

Also, in the drawings used in the embodiments, hatching is partially used in some cases even in a plan view so as to make the drawings easy to see.

Hereinafter, embodiments of the present invention will be described in detail with reference to the accompanying drawings.

### First Embodiment

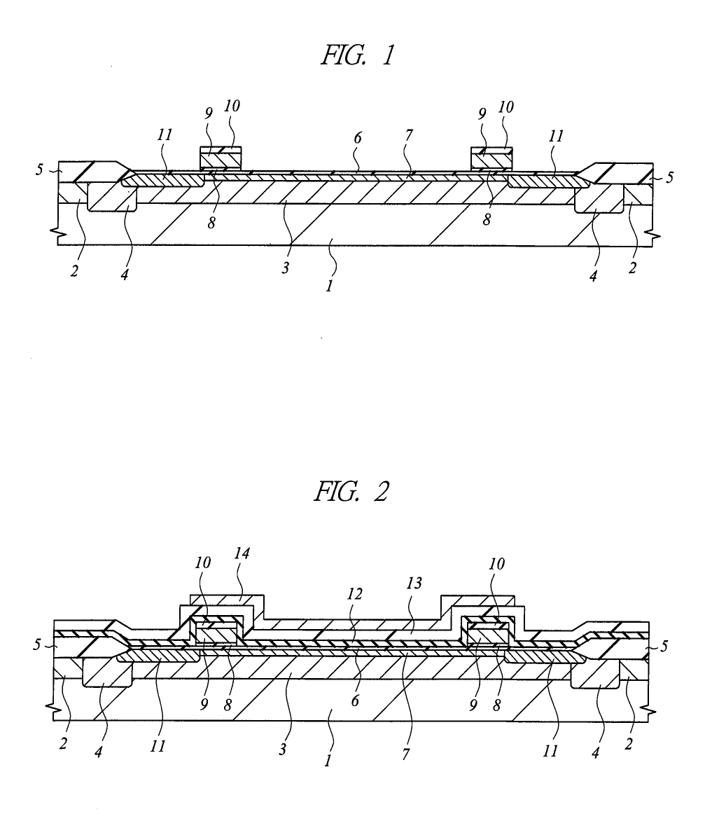

A semiconductor device according to a first embodiment is, for example, a pH image sensor based on MEMS. The semiconductor device according to the first embodiment and a manufacturing process thereof will be described below with reference to FIGS. 1 to 15.

First, as shown in FIG. 1, an impurity (for example, P (phosphorus)) having an n-type conductivity and an impurity (for example, BF₂ (boron difluoride)) having a p-type conductivity are selectively introduced into a main surface (device formation surface) of a semiconductor substrate (hereinafter, simply referred to as a substrate) 1 made of, for example, single crystal silicon, thereby forming an n-type well 2 and a p-type well 3. Next, an impurity (for example, BF₂) having the p-type conductivity is introduced into the main surface of the substrate 1, thereby forming a p-type well 4.

Subsequently, a silicon nitride film is deposited on the main surface of the substrate 1, and the silicon nitride film is etched with using a photoresist film pattered by photolithographic technique as a mask. Next, the substrate 1 is subjected to heat treatment with using the remaining silicon nitride film as a mask, thereby forming a field insulating film 5. By forming this field insulating film 5, an active region, in which a sensor element is to be formed, is defined on the main surface of the substrate 1.

Subsequently, after the silicon nitride film is removed, the substrate 1 is subjected to heat treatment, thereby forming a thin silicon oxide film 6. Next, an impurity (for example, P) having the n-type conductivity is introduced into the main surface of the substrate 1, thereby forming an n⁻-type semiconductor region 7.

Subsequently, the substrate 1 is subjected to heat treatment, thereby forming a thin silicon oxide film on the main surface of the substrate 1. Next, a polycrystalline silicon film and a silicon oxide film are sequentially deposited on the main surface of substrate 1. Next, the silicon oxide film, the polycrystalline silicon film and the thin silicon oxide film are etched with using a photoresist film pattered by the photolithographic technique as a mask, thereby forming gate insulating films 8 made of the thin oxide silicon film, gate electrodes (first electrode) 9 made of the polycrystalline silicon film and cap insulating films 10 made of the silicon oxide film.

Subsequently, the impurity (for example, P) having the n-type conductivity is selectively introduced into the main surface of the substrate 1 with using a photoresist film pattered by the photolithographic technique as a mask, thereby forming n⁺-type semiconductor regions 11. Through the process described above, a MOS transistor structure (sensor element) can be formed.

Next, as shown in FIG. 2, a silicon nitride film is deposited on the main surface of the substrate 1, thereby forming a sensor film (first thin film) 12. Next, a silicon oxide film is deposited on the sensor film 12, thereby forming an interlayer insulating film (first insulating film) 13.

Subsequently, for example, a polycrystalline silicon film is deposited on the interlayer insulating film 13, thereby forming an etching stopper film (second thin film) 14. As this etching stopper film 14, a material whose etching selectivity is different from the interlayer insulating film 13 formed therebelow and the interlayer insulating film formed thereon is applied. In the first embodiment, though a case in which a polycrystalline silicon film is used as the etching stopper film 14 when these interlayer insulating films are formed of the silicon oxide film has been illustrated, a conductive film or an insulating film such as a Ti (titanium) film, a TiN (titanium nitride) film, a W (tungsten) film, a TiW (titanium tungsten) film, an Al (aluminum) film, a silicon nitride film or the like may be used as the etching stopper film 14.

Subsequently, the etching stopper film 14 is patterned by etching using a photoresist film patterned by the photolithographic technique as a mask. At this time, the etching stopper film 14 is patterned so as to be left at least on a region (first region) functioning as a pH sensor.

Next, as shown in FIG. 3, a silicon oxide film is deposited on the substrate 1 by, for example, a CVD method, thereby forming an interlayer insulating film (second insulating film) 15. Next, a surface of the interlayer insulating film 15 is polished and flattened by a CMP (Chemical Mechanical Polishing) method.

Subsequently, the interlayer insulating films 15, 13 and the sensor film 12 are etched with using a photoresist film patterned by the photolithographic technique as a mask, thereby forming contact holes 16 reaching the n⁺-type semiconductor regions 11. Next, a barrier conductive film is formed by depositing a Ti film, a TiN film or a laminated film thereof on the interlayer insulating film 15 including the inside of the contact holes 16. Next, for example, an Al film is deposited on the barrier conductive film by a sputtering method. At this time, the Al film fills the contact holes 16. Next, the Al film and the barrier conductive film are etched with using a photoresist film patterned by the photolithographic technique as a mask, thereby forming wirings 17.

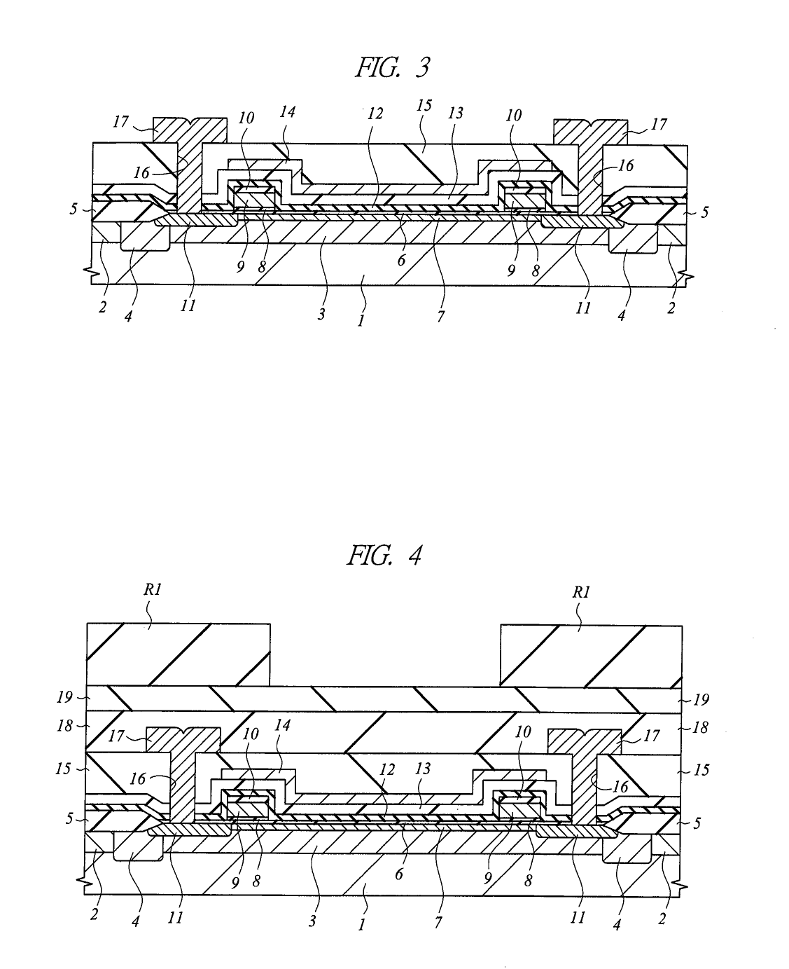

Next, as shown in FIG. 4, for example, a silicon oxide film is deposited on the substrate 1 by the CVD method, thereby forming an interlayer insulating film (second insulating film) 18. A total film thickness of the interlayer insulating films 15 and 18 is larger than the film thickness of the interlayer insulating film 13. Next, after a surface of the interlayer insulating film 18 is polished and flattened by, for example, the CMP method, a silicon nitride film is deposited on the interlayer insulating film 18, thereby forming a surface protection film (second insulating film) 19. Next, a photoresist film R1 is deposited on the surface protection film 19, and the photoresist film R1 is patterned by the photolithographic technique. By this patterning, the photoresist film R1 above the region functioning as the pH sensor is removed.

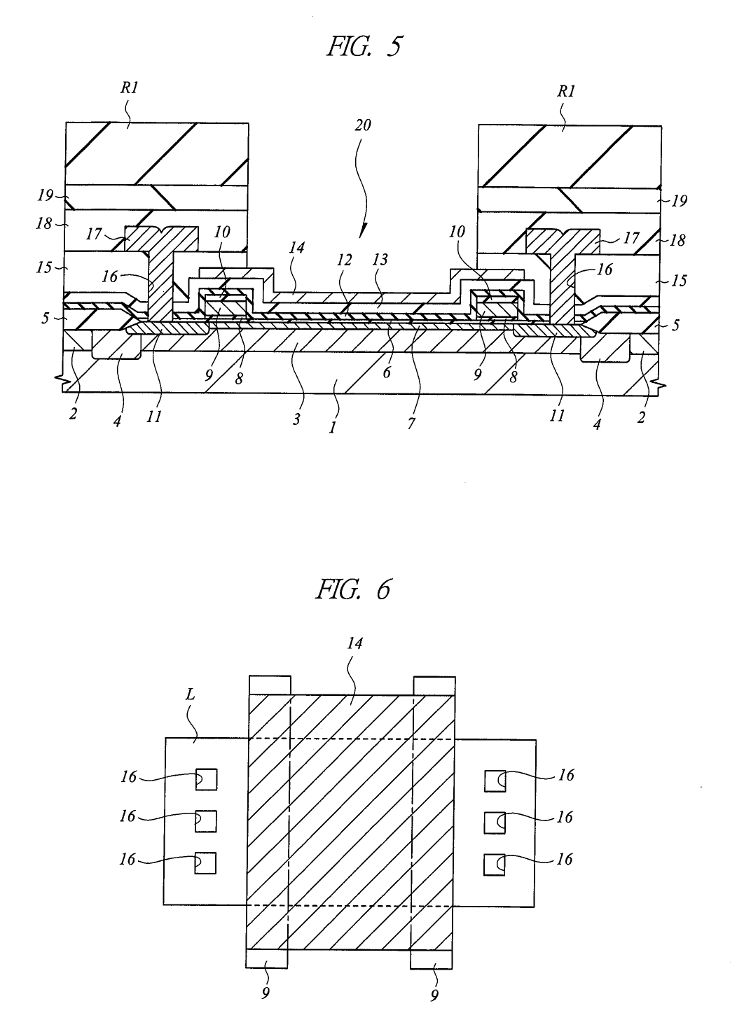

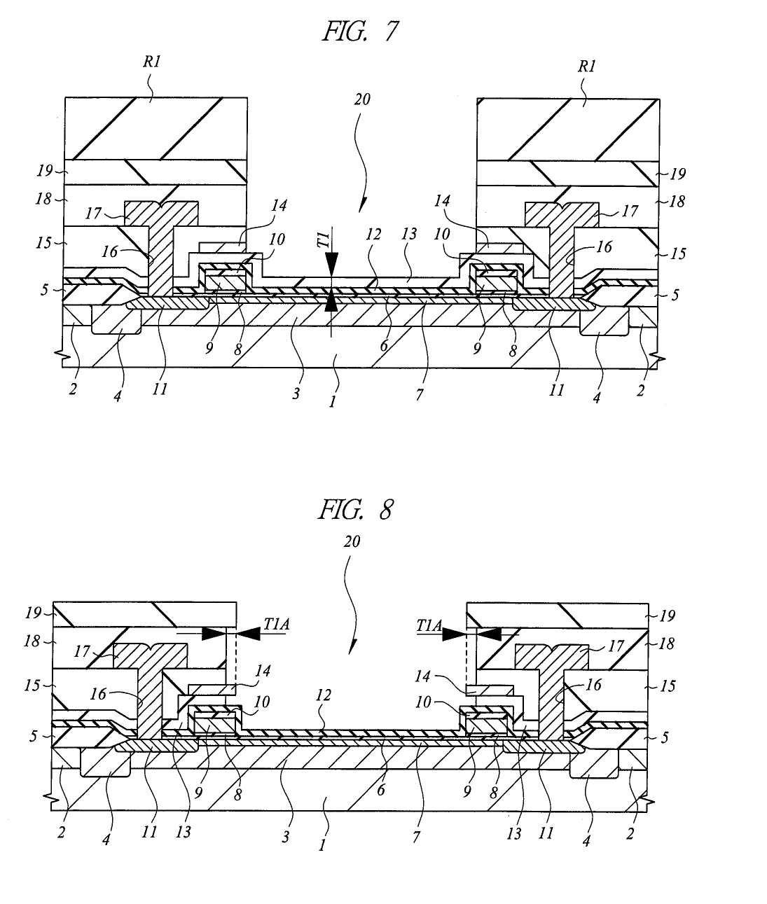

Next, as shown in FIG. 5, the surface protection film is dry-etched with using the photoresist film (first masking layer) R1 as a mask, thereby forming an opening 20 having a desired opening shape (first planer shape). Since the silicon nitride film as the surface protection film 19 is different in etching selectivity from the silicon oxide film as the interlayer insulating film 18 formed therebelow, the interlayer insulating film 18 can serve as an etching stopper in this dry etching process.

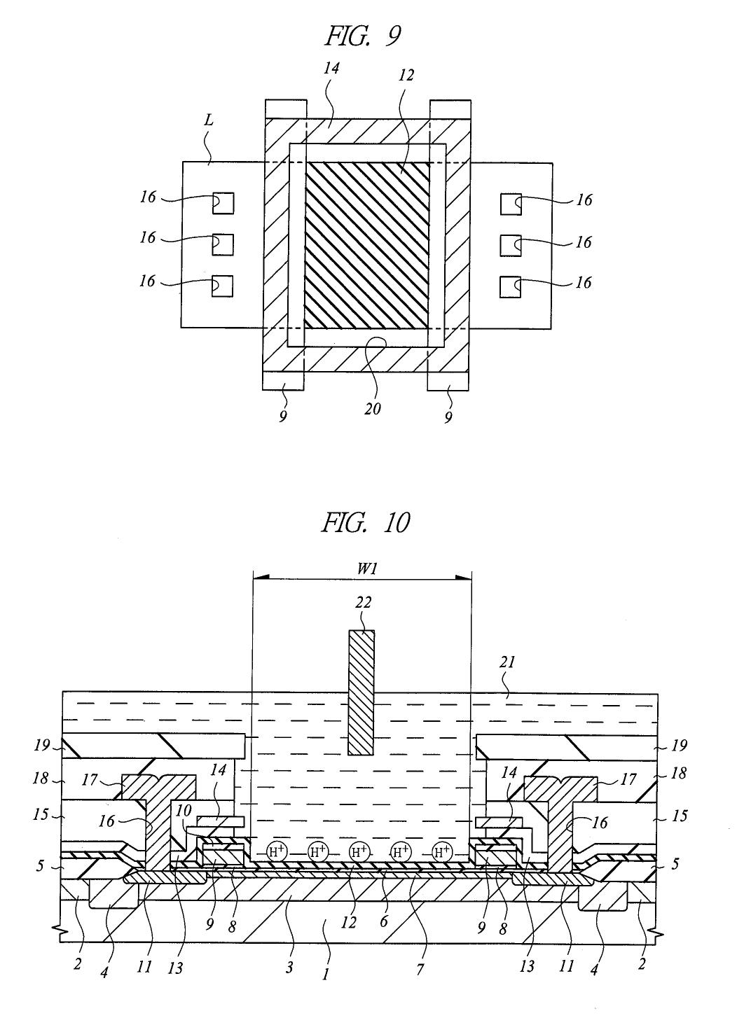

Subsequently, the interlayer insulating films 18 and 15 are dry-etched with using the photoresist film R1 and the surface protection film 19 having the opening 20 formed therein as a mask, thereby expanding the opening 20 downward. As described above, a material for the etching stopper film 14 below the interlayer insulating film 15 is selected so that etching selectivity is different from that of the upper and lower interlayer insulating films. Therefore, the dry etching can be stopped by the etching stopper film 14 at the dry etching process of the interlayer insulating films 18 and 15. Further, FIG. 6 is a plan view of the principal part showing a positional relation on the planer surface of an active region L whose range is defined by the field insulating film 5, the gate electrode 9 and the etching stopper film 14, and the etching stopper film 14 is shown with hatching.

The dry etching of the surface protection film 19 and the interlayer insulating films 18 and 15 is anisotropic etching, in which etching in a lateral direction is quite small.

Next, as shown in FIG. 7, the etching stopper film 14 below the opening 20 is dry-etched, thereby expanding the opening 20 downward. As described above, since a material for the etching stopper film 14 is selected so that etching selectivity is different from that of the lower interlayer insulating film 13, the dry etching can be stopped by the interlayer insulating film 13 at the dry etching process of the etching stopper film 14.

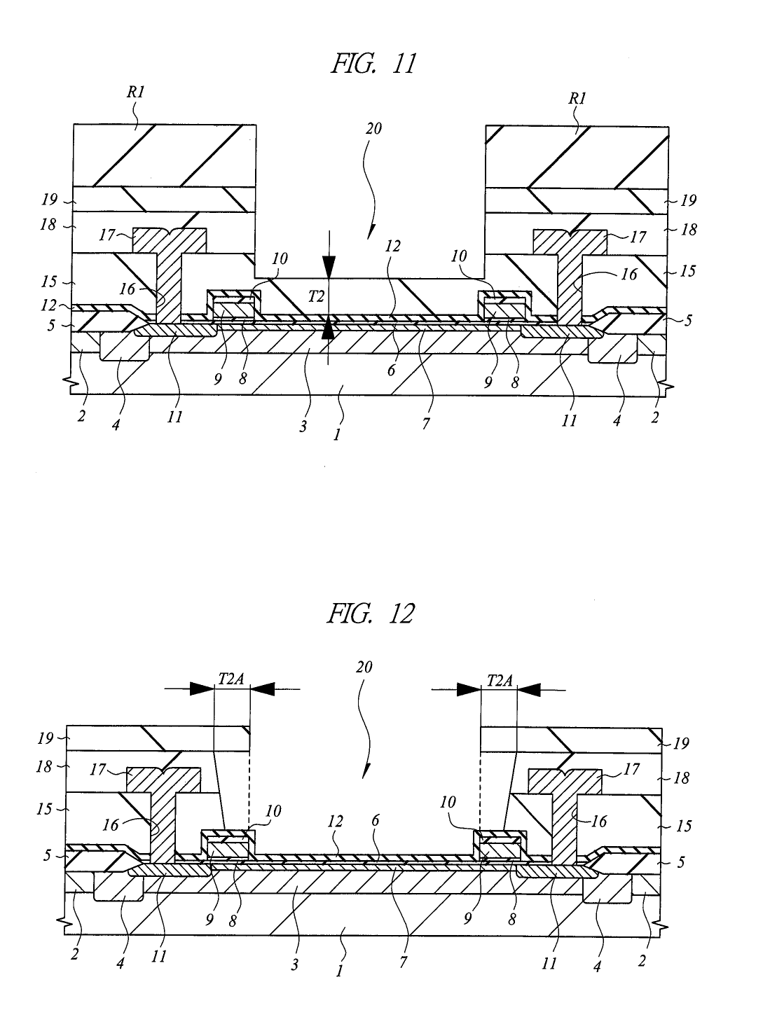

Next, as shown in FIG. 8, after the photoresist film R1 is removed, the interlayer insulating film 13 below the opening 20 is wet-etched, and the sensor film 12 on a whole bottom surface and on a part of the side surface of the opening 20 is exposed. Since this wet etching is isotropic etching, the side etching shown by T1A equal to or more than the thickness T1 (see FIG. 7) of the interlayer insulating film 13 is caused not only in the interlayer insulating film 13 but also in the interlayer insulating films 15 and 18 made of the same silicon oxide film as the interlayer insulating film 13. This is because the over-etching is performed to completely remove the interlayer insulating film 13 on the sensor film 12 below the opening 20, and even if downward (film thickness direction of the substrate 1) etching is stopped, the side etching proceeds at the time of over-etching. In the first embodiment, the side etching amount shown by this T1A can be suppressed to about several times the thickness T1 of the interlayer insulating film 13. FIG. 9 is a plan view of the principal part at the time when the wet etching of the insulating film 13 is performed, and the etching stopper film 14 and the sensor film 12 below the opening 20 are shown with hatching. Although the detail thereof will be described later, the sensor film 12 exposed at the bottom of this opening 20 functions as the pH sensor. In the present embodiment, the exposure of the sensor film 12 means that the sensor film 12 is not covered with the upper interlayer insulating films 13, and 18, the etching stopper film 14 and the surface protection film 19, and a natural oxide film and the like which are sometimes naturally formed on the surface should not be included.

As shown in FIG. 10, in the pH image sensor of the first embodiment, the opening 20 is immersed into a test solution 21 and an electrode 22 is inserted into the test solution 21 to apply a potential thereto to operate a MOS transistor, so that a pH of the test solution 21 is calculated based on a characteristic of the MOS transistor that fluctuates depending on the density of H ion (H⁺ (measured material)) adsorbed by the sensor film 12 at this time. Therefore, the sensor film 12 on the side surface of the gate electrode 9 must be exposed to the side surface of the opening 20. Further, in addition to that the sensor film 12 must be exposed, when the opening 20 is processed, the reduction of the H ion adsorption ability of the sensor film 12 exposed to the bottom of the opening 20 needs to be prevented. When the silicon nitride film as the sensor film 12 is exposed to a dry etching atmosphere of the silicon oxide film as the interlayer insulating films 15 and 18, the H ion adsorption ability is reduced. Hence, in the first embodiment, the interlayer insulating film 13 directly above the sensor film 12 is removed by the wet etching, so that the reduction of the H ion adsorption ability of the sensor film 12 can be prevented. Note that the part of the sensor film 12 shown by W1 is a part actually functioning as the sensor.

Further, according to the first embodiment, after the formation of the opening 20 (after the wet etching), the etching stopper film 14 protrudes by a predetermined amount from a side wall of the opening 20. Hence, if a layout of the opening 20 is formed in such a manner that planer (opening) dimensions of the opening 20 in the etching stopper film 14 are made small, the opening can be made to function as a filter by which unnecessary materials affecting the pH measurement in the test solution 21 are filtered by the etching stopper film 14, and it is possible to prevent the unnecessary materials from reaching the sensor film 12. As a result, the measurement accuracy of the pH value of the test solution 21 can be improved.

Further, with respect to the film thickness of the etching stopper film 14, there are the cases where it is made thicker than the gate electrode 9 and it is made thinner than the gate electrode 9 based on the thickness of the gate electrode 9.

When the film thickness of the etching stopper film 14 is made larger than that of the gate electrode 9, since a mechanical strength of the etching stopper film 14 can be improved, a protruding amount from the side wall of the opening 20 can be made large. By this means, the above-described function as the filter can be improved.

As a case in which the film thickness of the etching stopper film 14 is made smaller than that of the gate electrode 9, a case can be illustrated, in which the etching stopper film 14 is formed of the same silicon nitride film as the sensor film 12 and a protruding portion from the side wall of the opening 20 is made small with the intention of reducing the material adsorbed (filtered) by the etching stopper film 14. Since a strength required for supporting the protruding portion from the side wall of the opening 20 can be lessen by forming the etching stopper film 14 to have a small thickness in this manner, the etching stopper film 14 remaining between the interlayer insulating film 13 and the interlayer insulating film 15 can be made small.

Further, with respect to the interlayer insulating film 13, when the thickness thereof is too large, a side etching amount of the interlayer insulating films 15 and 18 at the time of wet etching of the interlayer insulating film 15 increases, whereas when the film thickness thereof is too small, an electric charge of the unnecessary materials adsorbed (filtered) by the etching stopper film 14 protruding from the side wall of the opening 20 affects the sensor film 12, and there is a fear that an erroneous pH measurement result of the test solution 21 is obtained. Although such a film thickness of the interlayer insulating film 13 can be appropriately set in conformity to the test solution 21 to be measured, the first embodiment illustrates the case in which the film thickness of the interlayer insulating film 13 is made equal to or larger than the film thickness of the gate insulating film 8.

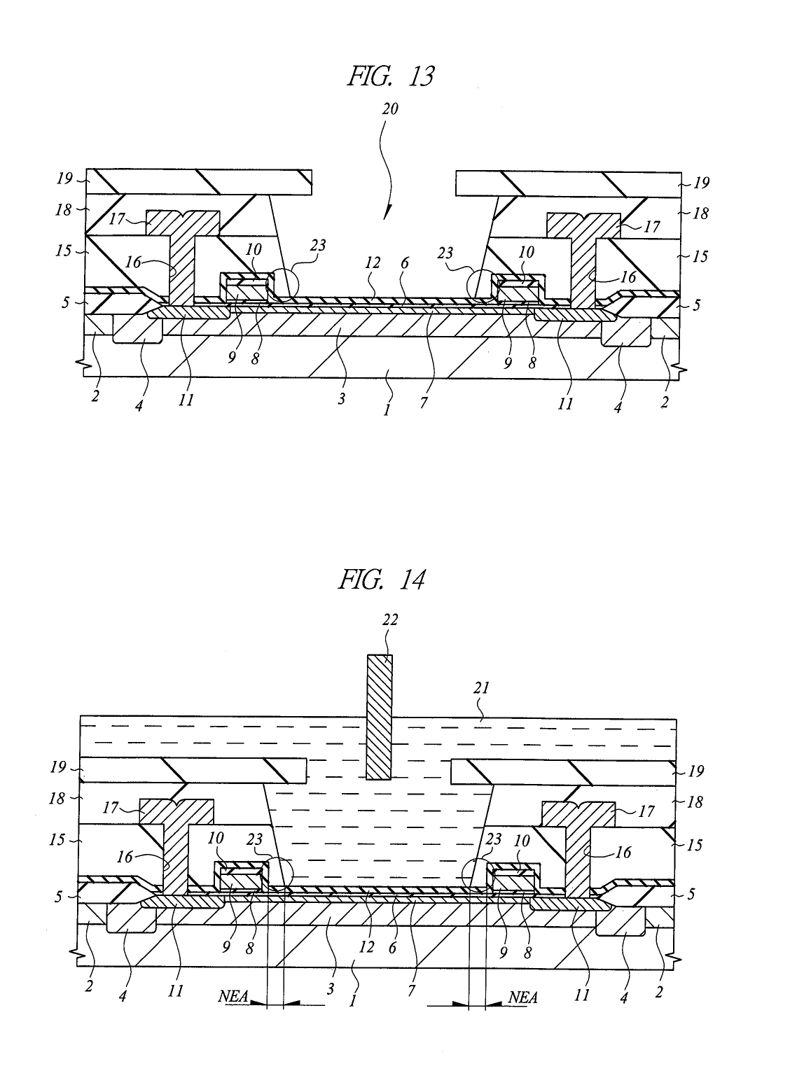

Incidentally, a structure in which the etching stopper film 14 is omitted is also conceivable. In this case, when the over-etching by the dry etching of the interlayer insulating film 15 excessively proceeds, there is a fear that the sensor film 12 is exposed to a dry etching atmosphere of the interlayer insulating film 15 and the H ion adsorption ability of the sensor film 12 is reduced, and since it is difficult to stop the dry etching of the interlayer insulating film 15 immediately before the sensor film 12, the dry etching needs to be stopped while giving a margin to a remaining thickness T2 of the interlayer insulating film 15 (see FIG. 11). Thereafter, the interlayer insulating film 15 is wet-etched by the remaining thickness T2, but as described above, the side etching of the interlayer insulating films 15 and 18 is also caused at the wet etching, and the side etching amount (T2A) increases along with an increase of the remaining thickness T2 of the interlayer insulating film 15 (see FIG. 12). Therefore, when the remaining thickness T2 of the interlayer insulating film 15 becomes large, there is a fear of causing a trouble that the opening 20 cannot be processed according to the design dimensions if an opening diameter (W1) of the opening 20 becomes microscopic. Further, a by-product material is generated at the dry etching of the interlayer insulating films 15 and 18, and this by-product material becomes a polymer 23 and is deposited from the bottom of the opening 20 to the underpart of the sidewall. This polymer 23 obstructs the proceeding of the wet etching of the remaining thickness T2 of the interlayer insulating film 15, and is liable to remain even after the wet etching (see FIG. 13). When the polymer 23 like this remains unremoved, a region NEA shown in FIG. 14 in which an electric field is not applied at the operation of the pH image sensor is formed, and there is a fear that the MOS transistor is unable to operate and cannot function as the pH image sensor.

On the other hand, according to the first embodiment using the etching stopper film 14, the film thickness of the interlayer insulating film 13 below the etching stopper film 14 is kept small, so that the side etching amount (T1A) of the interlayer insulating films 15 and 18 at the wet etching of the interlayer insulating film 13 can be suppressed as small as possible. By this means, it is possible to accurately process the interlayer insulating films even when the opening 20 is minutely designed.

Also, according to the first embodiment using the etching stopper film 14, the polymer generated at the dry etching of the interlayer insulating films 15 and 18 is attached on the etching stopper film 14. Since the polymer attached on the etching stopper film 14 can be removed at the dry etching (see FIG. 7) of the etching stopper film 14, it is possible to prevent the polymer from remaining after the wet etching of the interlayer insulating film 13. Accordingly, it is possible to prevent a trouble that the pH image sensor of the first embodiment becomes unable to perform the MOS transistor operation.

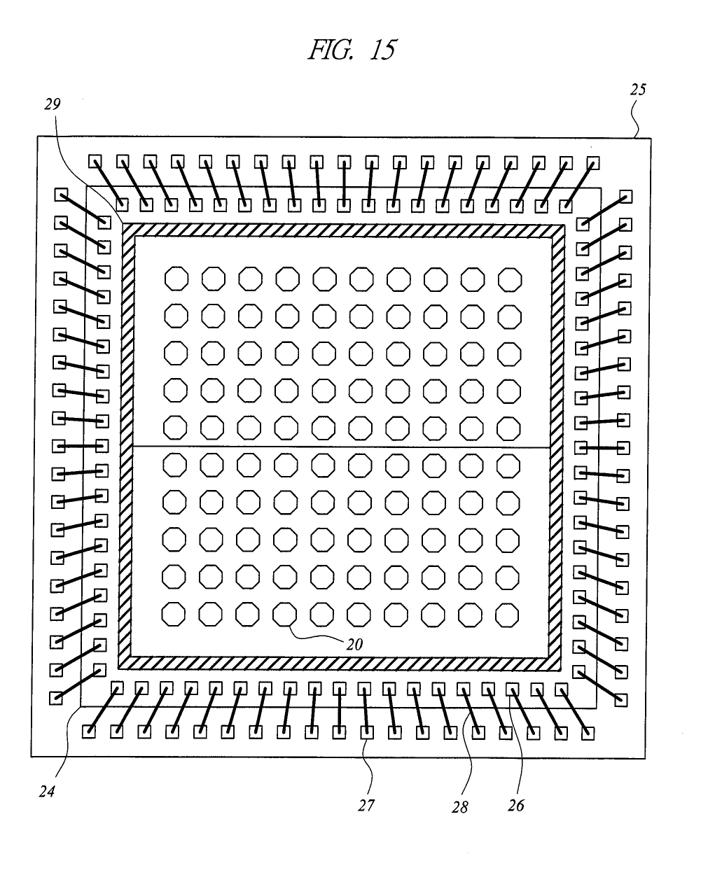

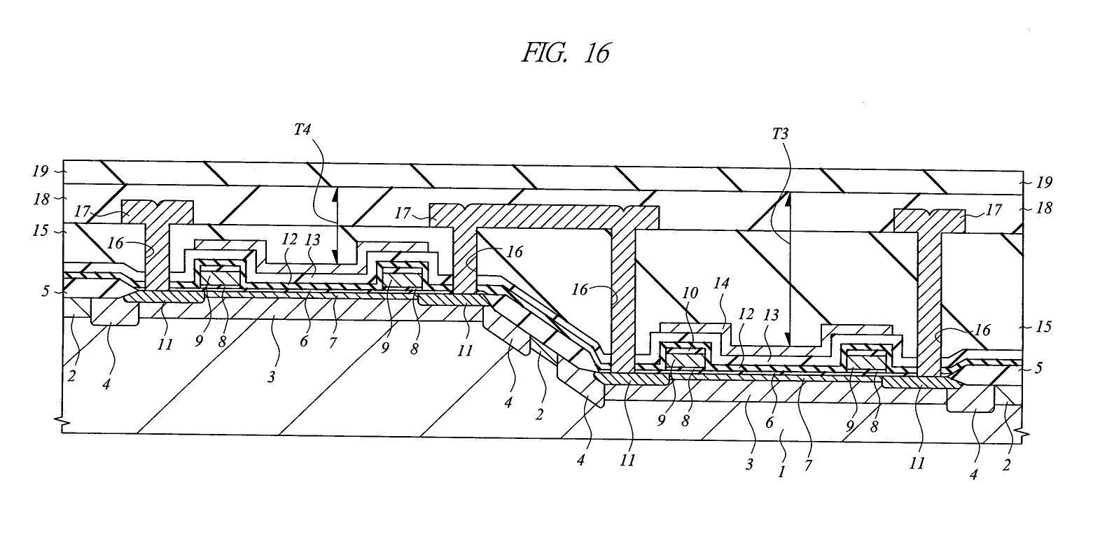

Thereafter, as shown in FIG. 15, a semiconductor chip (hereinafter, simply referred to as chip) 24 obtained by cutting the substrate 1 into individual pieces is mounted on a multilayer wiring board 25, and the pH image sensor of the first embodiment is thus manufactured. The chip 24 is provided with bonding pads 26 electrically connected to the wirings 17, and the bonding pads 26 and bonding pads 27 formed on the multilayer wiring board 25 are connected to each other by boding wires 28, so that the chip 24 and the multilayer wiring board 25 are electrically connected to each other. Further, a resin-made frame 29 is placed on the surface of the chip 24 so as to isolate the region in which the opening 20 is formed and the region in which the bonding pads 26 are formed. When measuring the pH of the test solution 21, the test solution 21 is supplied inside this frame 29, and the frame 29 prevents the test solution 21 from overflowing outside the frame 29.

In the first embodiment, ten lines of the openings 20 are arrayed in the chip 24 in longitudinal and lateral directions, respectively, and an array structure in which the bottom of each opening 20 serves as a sensor is formed. For example, a measurement result can be obtained by electrically connecting the multilayer wiring board 25 to a computer and displaying the pH measured under each opening 20 on the screen of the computer as a pH image figure in conformity to the array of each opening 20. Further, by changing the display color in conformity to the value, the measured pH can be modified to the measurement result easily understood visually.

Although the case in which only one wiring layer having the wiring 17 formed therein is formed has been described in the first embodiment, the wiring layers may be formed in a multilayer manner by repeating a process of forming the interlayer insulating film 15 and the wiring 17.

### Second Embodiment

A second embodiment shows a case in which the openings 20 described in the first embodiment are formed in a plurality of places each having different film thicknesses of the interlayer insulating films 15 and 18 on the sensor film 12 serving as a pH sensor.

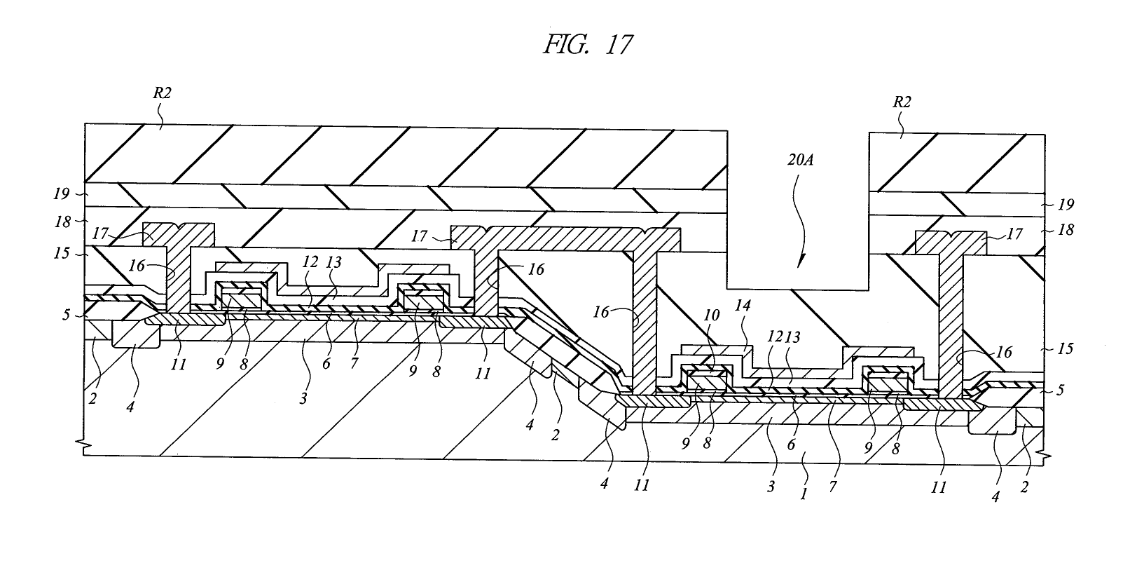

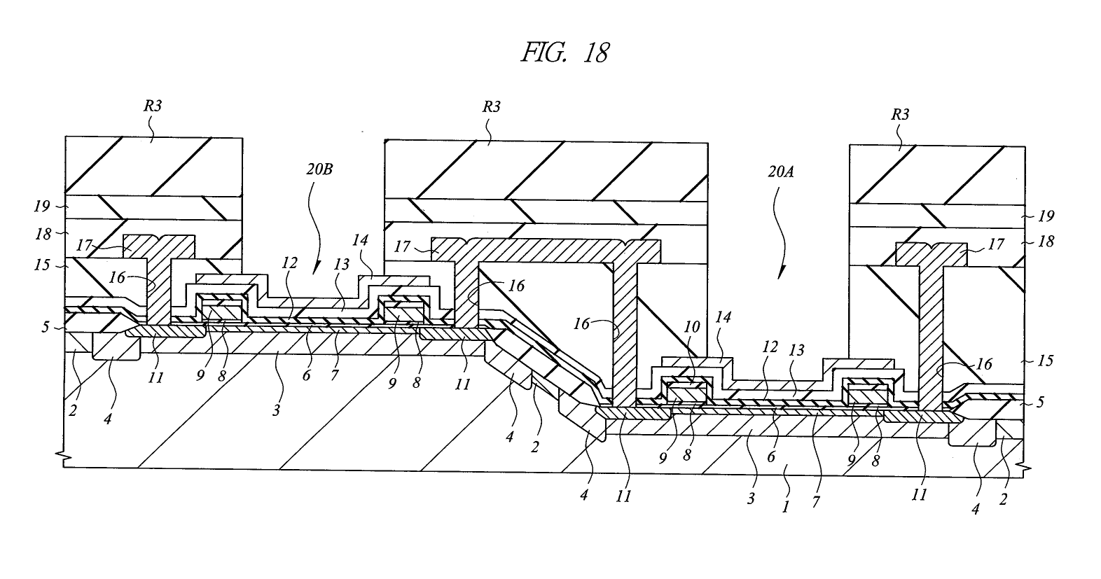

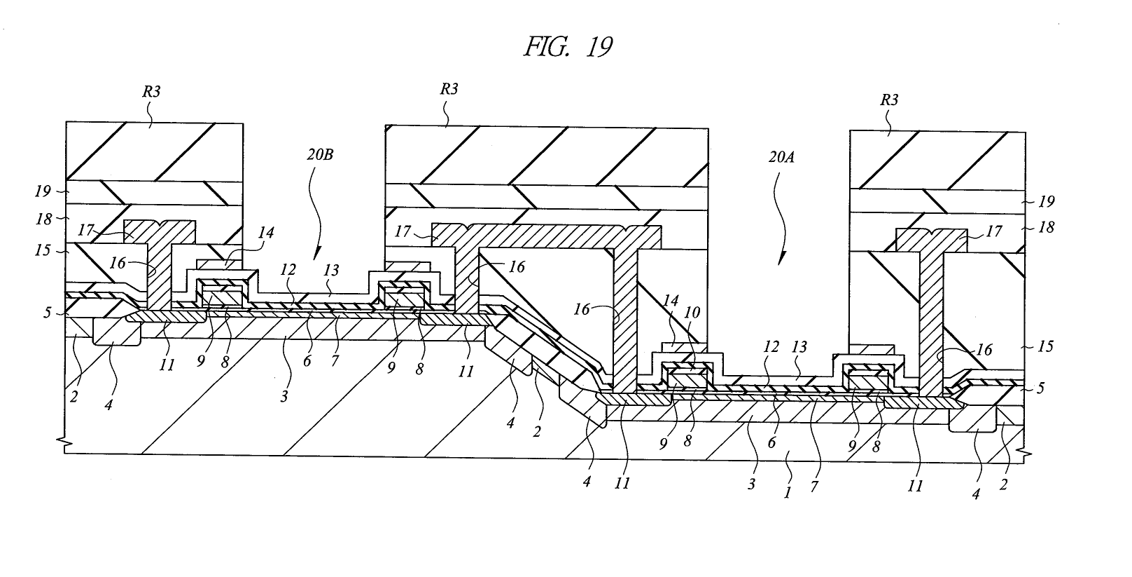

In the second embodiment, as shown in FIG. 16, a plurality of openings are provided on the sensor film 12 serving as the pH sensor, and a plurality of MOS transistor structures (first sensor element and second sensor element) for measuring the pH are provided so as to correspond to a plurality of openings. Although the processes until forming the surface protection film 19 are approximately the same as the manufacturing process described in the first embodiment, there are places where a total film thickness of the interlayer insulating films 15 and 18 is relatively large (T3) and relatively small (T4) depending on the place to which the opening is provided. In such a case, as shown in FIG. 17, in a region (first region) having a relatively large total film thickness T3 of the interlayer insulating films 15 and 18 (see FIG. 16), the surface protection film 19 is dry-etched with using a photoresist film R2 patterned by photolithographic technique as a mask, thereby forming an opening 20A. Next, the interlayer insulating films 18 and 15 are dry-etched with using the photoresist film R2 and the surface protection film 19 having the opening 20A formed therein as a mask, thereby expanding the opening 20A downward. At this time, the dry etching is stopped at the time when a total remaining thickness of the interlayer insulating films 18 and 15 below the opening 20A becomes approximately equal to the relatively small total film thickness T4 of the interlayer insulating films 15 and 18.

Next, as shown in FIG. 18, after the photoresist film R2 is removed, a photoresist film R3 patterned by the photolithographic technique is formed again on the surface protection film 19. Then, the surface protection film 19 of a region (second region) having a relatively small total film thickness T4 of the interlayer insulating films 15 and 18 (see FIG. 16) is dry-etched with using this photoresist film R3 as a mask, thereby forming an opening 20B. At this time, though the interlayer insulating film 15 below the opening 20A is also exposed to a dry etching atmosphere, since etching selectivity is different between the surface protection film 19 and the interlayer insulating film 15, only the surface protection film 19 can be selectively etched.

Subsequently, the interlayer insulating films 18 and 15 are dry-etched with using the photoresist film R3 and the surface protection film 19 having the openings 20A and 20B formed therein as a mask, thereby expanding the openings 20A and 20B downward. As described also in the first embodiment, a material for the etching stopper film 14 below the interlayer insulating film 15 is selected so that etching selectivity is different from that of the upper and lower interlayer insulating films. Therefore, at the dry etching process of the interlayer insulating films 18 and 15, the dry etching can be stopped by the etching stopper film 14.

Next, as shown in FIG. 19, the etching stopper films 14 below the openings 20A and 20B are dry-etched, thereby expanding the openings 20A and 20B downward. As described also in the first embodiment, since a material for the etching stopper film 14 is selected so that etching selectivity is different from that of the lower interlayer insulating film 13, the dry etching can be stopped by the interlayer insulating film 13 at the dry etching process of the etching stopper film 14.

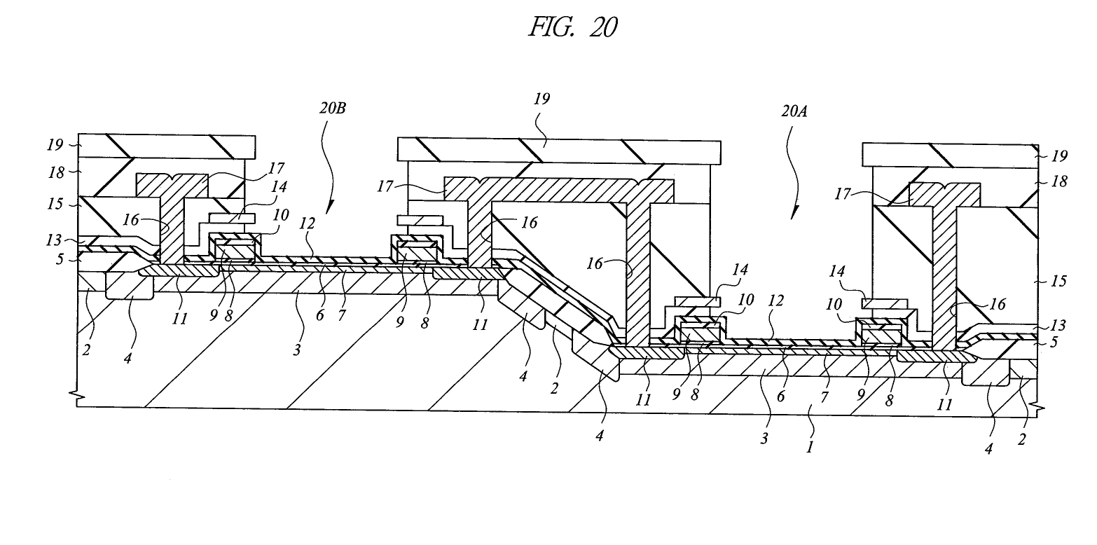

Next, as shown in FIG. 20, after the photoresist film R3 is removed, the interlayer insulating films 13 below the openings 20A and 20B are wet-etched, thereby exposing the sensor films 12 below the openings 20A and 20B. The sensor films 12 exposed to the bottom of these openings 20A and 20B function as the pH sensor.

Note that, in the dry etching of the interlayer insulating films 18 and 15, since the proceeding of the etching can be stopped by the etching stopper film 14, it is possible to perform the over-etching. Therefore, as a process of simultaneously forming the openings 20A and 20B, while the over-etching is performed in the region having the relatively small total film thickness T4 of the interlayer insulating films 15 and 18, etching of the interlayer insulating film 15 can be proceeded in the region having the relatively large total film thickness T3. By this means, the number of manufacturing processes of the pH image sensor of the second embodiment can be reduced, and TAT (Turn Around Time) can be shortened.

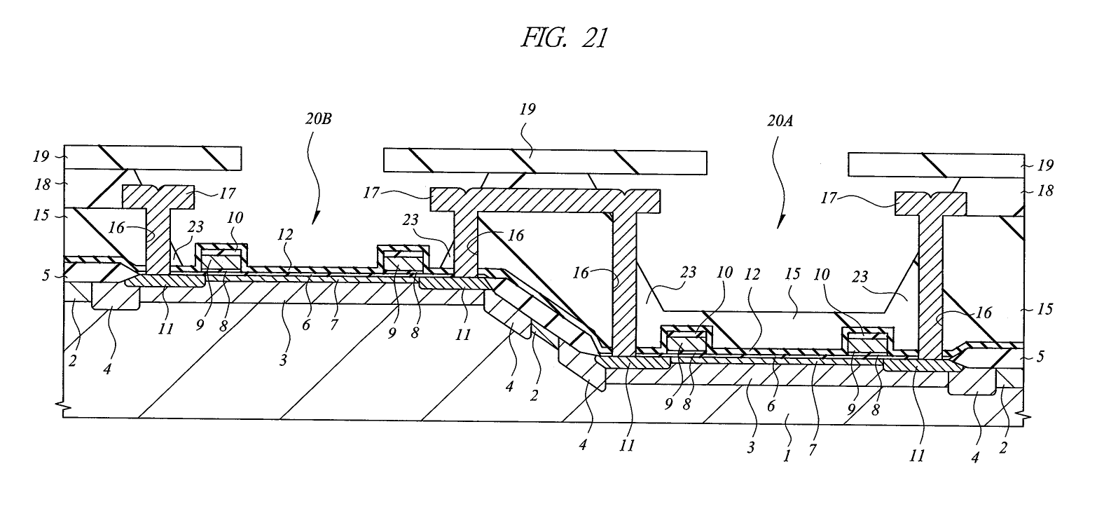

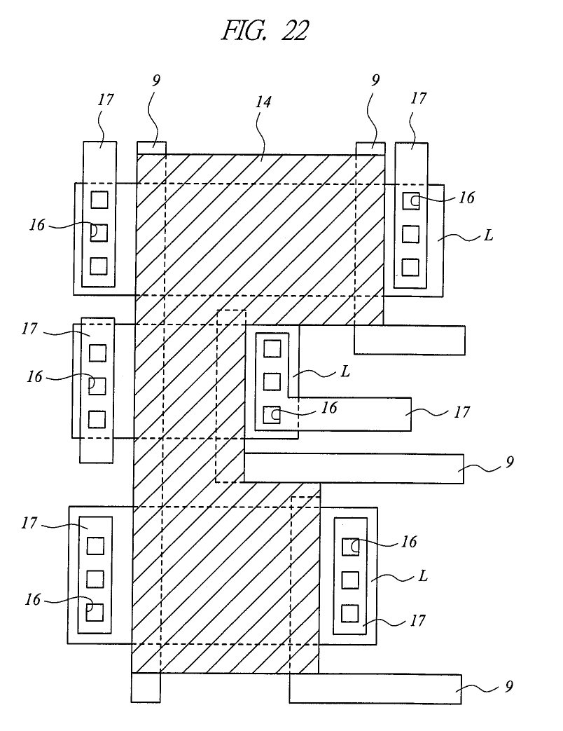

Here, FIG. 21 is a cross-sectional view showing an example in the case where the etching stopper film 14 is not formed. When the etching stopper film 14 is not formed, as described also in the first embodiment, the dry etching needs to be stopped while giving a margin to the remaining thickness of the interlayer insulating film 15 at the dry etching of the interlayer insulating films 15 and 18. However, when the opening 20B is formed after the opening 20A is formed as described above, since the dry etching needs to be stopped while giving a margin to the remaining thickness of the interlayer insulating film 15 even below the opening 20B before starting the wet etching, there is a fear that the fluctuation of the remaining thickness of the interlayer insulating film 15 each below the openings 20A and 20B at the time of the completion of the dry etching process becomes large. Further, when the remaining thicknesses of the interlayer insulating films 15 below the openings 20A and 20B are large, since a subsequent etching amount becomes large and the side etching amount at the wet etching also becomes large, there is a fear that the wiring 17 is exposed. Also, when the fluctuation of the remaining thickness of the interlayer insulating film 15 each below the openings 20A and 20B is large, such a case may occur that, even if the interlayer insulating film 15 below the opening 20B is removed at the wet etching of the interlayer insulating film 15, the interlayer insulating film 15 below the opening 20A still remains. Further, when the wet etching is continued to remove the remaining interlayer insulating film 15 below the opening 20A, even the gate electrode 9 is exposed in a state of being covered with the sensor film 12 in the opening 20B, and there is a fear that even the opposite side of the gate electrode 9 is exposed.

On the other hand, according to the second embodiment in which the etching stopper film 14 is provided, the dry etching of the interlayer insulating films 15 and 18 can be surely stopped by the etching stopper film 14, and the film thickness of the interlayer insulating film 13 below the etching stopper film 14 can be uniformized below the openings 20A and 20B. Further, by forming the interlayer insulating film 13 below the etching stopper film 14 to have a small film thickness, a side etching amount (T1) of the interlayer insulating films 15 and 18 at the wet etching of the interlayer insulating films 13 can be suppressed as small as possible. As a result, even when the openings 20A and 20B are formed at a plurality of places each having different total film thicknesses of the interlayer insulating films 15 and 18, the openings 20A and 20B can be processed accurately. Naturally, it is also possible to process the openings 20A and 20B minutely.

### Third Embodiment

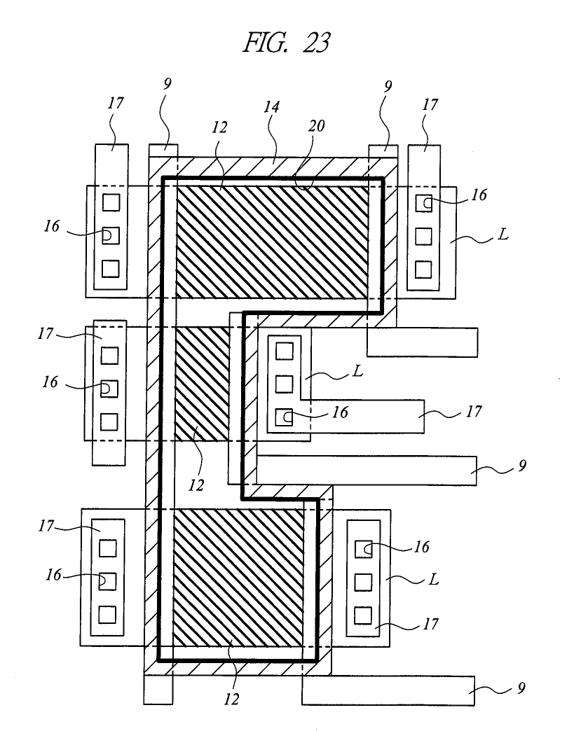

A third embodiment shows a case in which the planer (opening) shape of the opening 20 described in the first embodiment is complicated, and FIG. 22 is a plan view of the principal part before the formation of the opening 20 and FIG. 23 is a plan view of the principal part after the formation of the opening 20.

When the planer shape of the opening 20 is not a simple rectangular or round shape but has a complicated structure and the like, there are the cases where the gate electrode 9, the wiring 17 and the like are disposed in the complicated place. As described also in the first embodiment, when the opening 20 is formed by using the etching stopper film 14, a side etching amount of interlayer insulating films 15 and 18 (see FIG. 8) at the dry etching of the interlayer insulating film 13 (see FIG. 8) can be suppressed as small as possible. Accordingly, even when the planer shape of the opening 20 is complicated, the opening 20 can be formed to have a shape in conformity to a layout pattern with high dimensional accuracy.

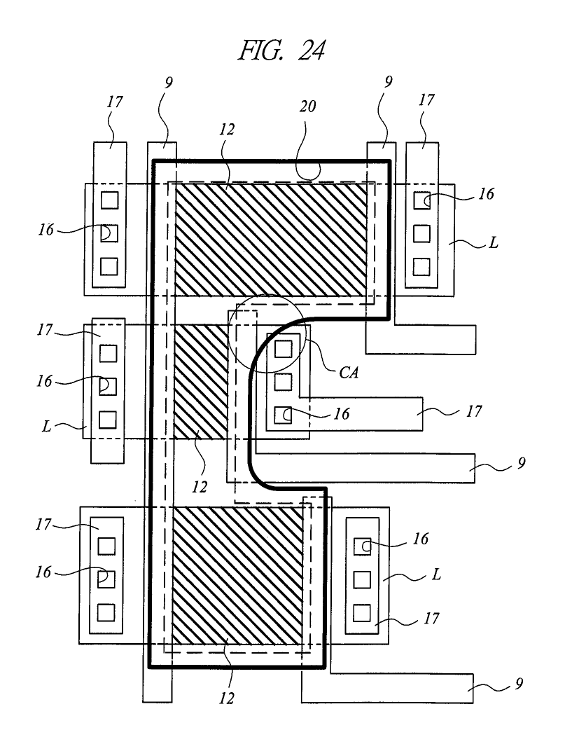

On the other hand, when the opening 20 is formed without forming the etching stopper film 14, as described also in the first embodiment, the side etching amount of the interlayer insulating films 15 and 18 at the wet etching of the interlayer insulating film 13 becomes large, and there is a fear that a desired planer shape cannot be obtained. As described above, when the gate electrode 9, the wiring 17 and the like are disposed in the complicated place (shown by a symbol CA in FIG. 24) of the opening 20, there is a fear of causing a trouble that the gate electrode 9, the wiring 17 and the like are exposed by the side etching (see FIG. 24).

### Fourth Embodiment

A fourth embodiment shows a case where the etching stopper film 14 remaining after the formation of the opening 20 described in the first embodiment is used as an electrode.

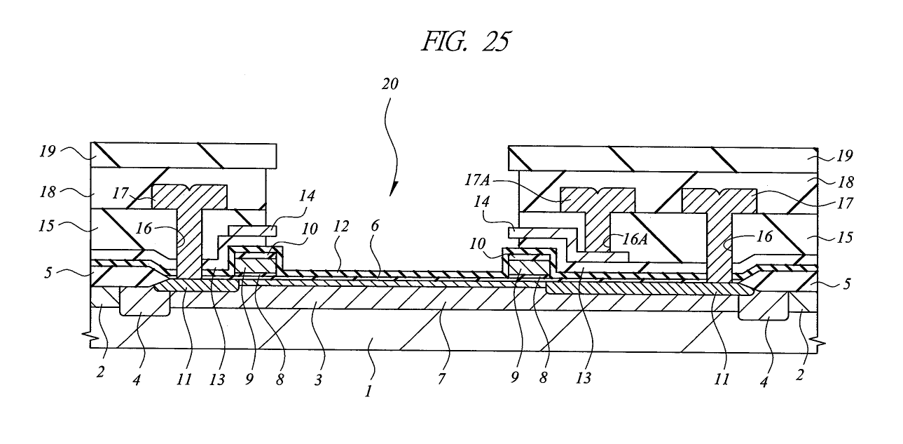

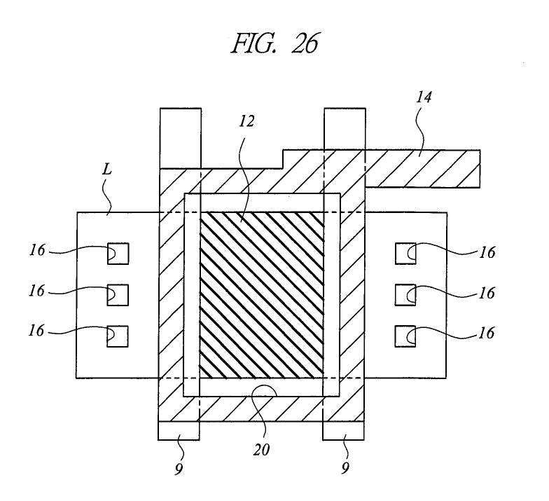

FIGS. 25 and 26 are a cross-sectional view and a plan view of the principal part at the time when the opening 20 is formed so as to reach the sensor film 12, respectively. As shown in FIGS. 25 and 26, in the fourth embodiment, a wiring (second electrode) 17A is formed by the same wiring layer as the wiring 17, and this wiring 17A is connected to the etching stopper film 14 through a contact hole 16A. In the fourth embodiment, since the etching stopper film 14 is used also as an electrode, even when the film is formed of a material other than polycrystalline silicon, a conductive material is selected.

According to a pH image sensor of the fourth embodiment having the above-described structure, a potential gradient can be generated between the test solution 21 and the etching stopper film 14 by applying a voltage between the electrode 22 and the etching stopper film 14 through the wiring 17A when measuring the pH of the test solution 21 (see FIG. 10). By generating the potential gradient like this, materials concentrated on the sensor film 12 during the pH measurement of the test solution 21 can be arbitrarily selected. More specifically, since the unnecessary materials affecting the pH measurement can be adsorbed to the etching stopper film 14 by the potential gradient, the measuring accuracy of the pH value of the test solution 21 can be improved. Further, since the unnecessary materials affecting the pH measurement can be adsorbed to the etching stopper film 14, a time-consuming process of filtering the test solution 21 to remove unnecessary materials before starting the measurement can be omitted, and the efficiency of the pH measurement can be improved.

Further, depending on characteristics such as a degree of ionization, positive and negative electric charges and a neutral characteristic in the test solution 21, a sensing sensitivity of the pH image sensor of the fourth embodiment can be changed by generating the potential gradient.

Also, the etching stopper film 14 can be used in place of the electrode 22. When the film 14 is used as an electrode, an electric field distribution from the etching stopper film 14 can be controlled by the following method. That is, since an interval between the sensor film 12 and the etching stopper film 14 is enlarged by increasing the film thickness of the interlayer insulating film 13 below the etching stopper film 14, an electric field can be uniformly applied from the etching stopper film 14 to the test solution 21. Further, since the interval between the sensor film 12 and the etching stopper film 14 can be narrowed by reducing the film thickness of the interlayer insulating film 13 below the etching stopper film 14, a gradient can be provided for the electric field applied to the test solution 21 from the etching stopper film 14.

### Fifth Embodiment

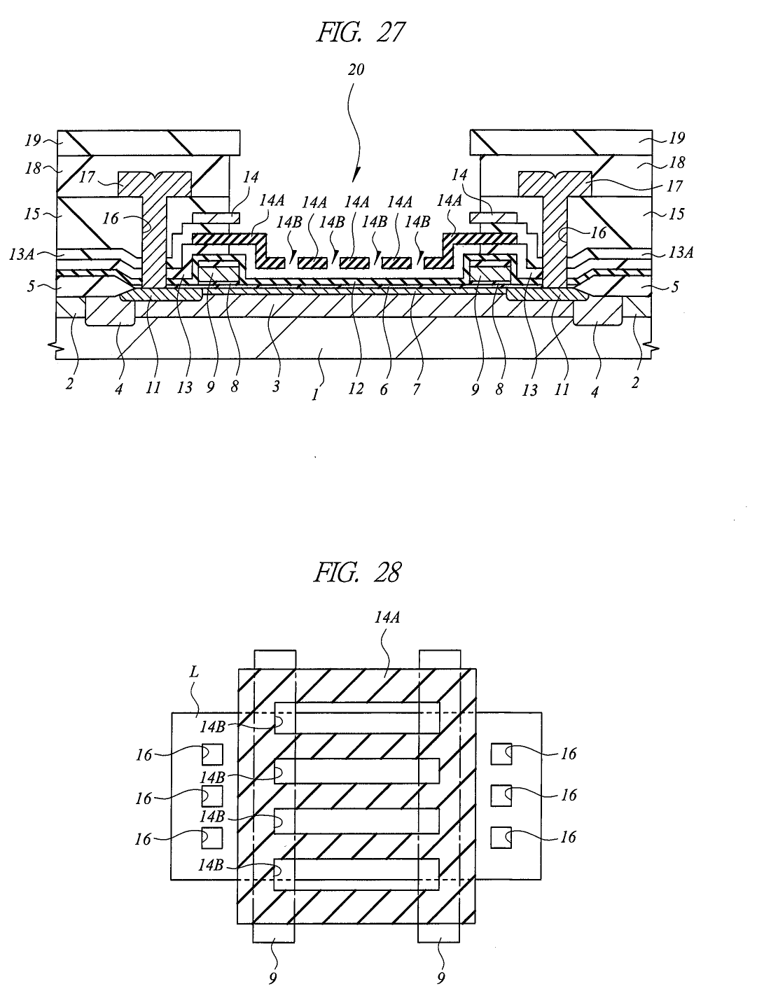

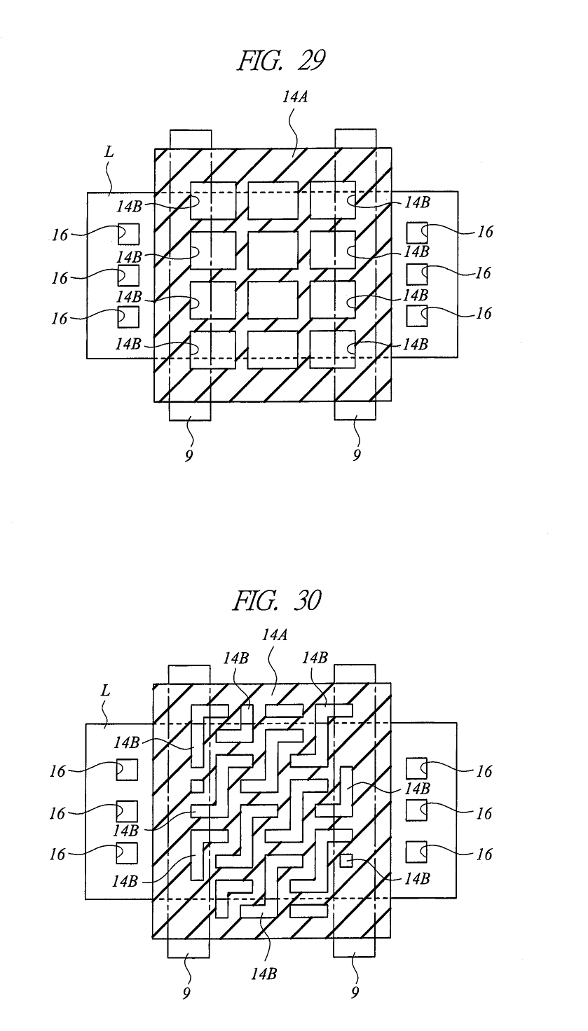

FIG. 27 is a cross-sectional view of the principal part of a pH image sensor as a semiconductor device according to a fifth embodiment, and FIGS. 28 to 30 are cross-sectional views of the principal part of the image sensor.

As shown in FIGS. 27 to 30, in the pH image sensor according to the fifth embodiment, a net film (third thin film) 14A patterned into a planer net-like shape (first pattern) and an interlayer insulating film 13A are sequentially disposed from below between the interlayer insulating film 13 and the interlayer insulating film 15 in the structure of the pH image sensor according to the first embodiment. Note that the interlayer insulating film 13A may be omitted.

As the net film 14A, a material different in etching selectivity from those of the interlayer insulating films 13, 13A, 15 and 18 is used, and a conductive film or an insulating film such as a silicon nitride film similar to the sensor film 12 or a Ti film, a TiW film, a W film or the like is used. When the interlayer insulating film 13A is omitted, a material different in etching selectivity also from that of the etching stopper film 14 is used. The net film 14A is deposited on the interlayer insulating film 13 after the formation of the interlayer insulating film 13, and is pattered by etching using a photoresist film patterned by a photolithographic technique as a mask. By this patterning, a plurality of openings 14B having a desired planer shape as shown in FIGS. 28 to 30 are formed in the net film 14A of a region in which the opening 20 (pH sensor) is to be formed, and in this region, the net film 14A becomes a planer net-like pattern. Since the net film 14A is made of a material different in etching selectivity from those of the interlayer insulating films 13, 15 and 18 (and the etching stopper film when the interlayer insulating film 13A is omitted), the net film 14A having a planer net-like pattern formed therein can remain unremoved in the opening 20 even after the opening 20 is expanded to the sensor film 12.

As the interlayer insulating film 13A, a silicon oxide film similar to the interlayer insulating films 13, 15 and 18 can be used, and is deposited after the patterning of the net film 14A. The interlayer insulating film 13A like this can be isotropically etched together with the interlayer insulating film 13 in the wet etching process of the interlayer insulating film 13 for forming the opening 20 described also in the first embodiment.

Further, as shown in FIG. 27, a gap made by the etching of the interlayer insulating film 13 is formed between the net film 14A and the sensor film 12. When measuring the pH of the test solution 21 (see FIG. 10), since the test solution 21 enters into the gap between the net film 14A and the sensor film 12, the pH image sensor of the fifth embodiment can operate.

By providing the above-described net film 14A having the openings 14B formed therein, the material reaching the sensor film 12 when measuring the pH of the test solution 21 can be sorted by size, and it is possible to prevent a large material from reaching the sensor film 12.

Further, by providing the above-described net film 14A having the openings 14B formed therein, the material reaching the sensor film 12 when measuring the pH of the test solution 21 can be sorted also by shape in addition to size. More specifically, the shape of the openings 14B is formed in conformity to the shape of a material desired to pass through, whereby the net film 14A can be utilized so that a molecule with a certain shape (long and thin molecule) out of organic materials such as a protein and the like in the test solution 21 can pass through and a molecule with another shape (short and thick) can be filtered and removed.

Further, if the material of the net film 14A is appropriately selected, a specific material in the test solution 21 can be adsorbed by the net film 14A. For example, when two kinds of enzyme A and enzyme B having similar size and shape are present in the test solution 21 and the enzyme B is not wanted to be adsorbed to the sensor film 12, a material which adsorbs the enzyme B but not adsorb the enzyme A is selected as the net film 14A, whereby only the enzyme A is selected to reach the sensor film 12. Note that, although a silicon nitride film is used as the sensor film 12, in the case of a sensor in which the density of the adsorbed enzyme A is measured by using another thin film, the adsorption of the enzyme A by the sensor film 12 can be detected with good sensitivity by providing the net film 14A which selects and adsorbs only the enzyme B, and even when the net film 14A is unable to completely adsorb the enzyme B, a detection sensitivity of the enzyme A can be improved to some degree or another.

Further, if the filtration of unnecessary materials by the net film 14A is intended when measuring the pH of the test solution 21, a structure in which the etching stopper film 14 is omitted may be adopted.

In the foregoing, the invention made by the inventors of the present invention has been concretely described based on the embodiments. However, it is needless to say that the present invention is not limited to the foregoing embodiments and various modifications and alterations can be made within the scope of the present invention.

For example, in the above-described embodiment, the case where the pH sensor performs the MOS transistor operation and the pH value is measured based on the characteristic thereof has been described. Alternatively, a structure of a diode, a resistor, a capacitor and the like may be formed in place of the MOS transistor, and the pH value can be measured based on the characteristic thereof.

Further, in the above-described embodiment, the case where the pH value of the test solution is measured by using a silicon nitride film as the sensor film has been described, but another thin film such as a silicon oxide film, a polycrystalline silicon film, a Pt (platinum) compound film, an STO (Strontium-Titanium-Oxide) film, an amorphous silicon film, a Ti film, a TiW film, an organic film and the like may be used depending on an object (element) to be measured. For example, when a silicon oxide film is used, the measurement of a protein like DNA can be performed, and when an STO film is used, the measurement of gas can be performed. Further, when an organic film is used, a biosensor can be formed.

Also, in the above-described embodiment, the case where the pH image sensor is formed from a single crystal silicon substrate has been described, but a sensor may be formed by using another substrate such as GaAs (gallium arsenic), SiGe (silicon germanium) or the like in conformity to an object (element) to be measured.

### INDUSTRIAL APPLICABILITY

The semiconductor device and the manufacturing method thereof according to the present invention can be applied to a manufacturing process of a semiconductor device including a process using a dry etching method and a wet etching method together and a semiconductor device manufactured therefrom.

1. A semiconductor device comprising:
a sensor element formed on a main surface of a semiconductor substrate;
a first thin film formed on the main surface of the semiconductor substrate on which the sensor element has been formed;
a first insulating film formed on the main surface of the semiconductor substrate including the first thin film;
a second insulating film formed on the first insulating film;
a second thin film patterned between the first insulating film and the second insulating film on a first region of the main surface of the semiconductor substrate, and having etching selectivity to the first insulating film and the second insulating film; and
an opening formed in the first insulating film, the second insulating film and the second thin film, and reaching the first thin film,
wherein the sensor element is provided with a first electrode patterned on the main surface of the semiconductor substrate, and detects a material to be measured reaching the semiconductor substrate through the opening,
the first thin film covers an upper surface and a side surface of the first electrode, a bottom of the opening, and at least a part of a side surface of the opening,
the second thin film covers an upper surface of the first electrode,
a surface of the first thin film at the bottom of the opening and at least the part of the side surface of the opening is exposed, and
the first thin film is a thin film electrically operating the sensor element by the material to be measured.

2. The semiconductor device according to claim 1,
wherein the first insulating film is thinner than the second insulating film.

3. The semiconductor device according to claim 2,
wherein the second thin film is thicker than the first electrode.

4. The semiconductor device according to claim 2,
wherein the second thin film is thinner than the first electrode.

5. The semiconductor device according to claim 1,
wherein the opening has a complicated planer shape.

6. The semiconductor device according to claim 1,
wherein a second electrode capable of applying arbitrary potential is electrically connected to the second thin film.

7. The semiconductor device according to claim 1,
wherein the second thin film is formed of a conductive material, and potential of the second thin film can be arbitrarily set.

8. The semiconductor device according to claim 1,
wherein the first thin film is a silicon nitride film and adsorbs a hydrogen ion in a test solution to measure a pH of the test solution from a characteristic of the sensor element corresponding to an adsorption density of the hydrogen ion.

9. The semiconductor device according to claim 8,
wherein a plurality of the sensor elements and the openings are arranged to form an array, and a pH image figure in which an image of the pH corresponding to each of the openings is arranged is formed.

10. A semiconductor device comprising:
a sensor element formed on a main surface of a semiconductor substrate;
a first thin film formed on the main surface of the semiconductor substrate on which the sensor element has been formed;
a first insulating film formed on the main surface of the semiconductor substrate including the first thin film;
a second insulating film formed on the first insulating film;
a third thin film patterned with a first pattern between the first insulating film and the second insulating film on a first region of the main surface of the semiconductor substrate, and having etching selectivity to the first insulating film and the second insulating film; and
an opening formed in the first insulating film and the second insulating film, and reaching the first thin film,
wherein the sensor element is provided with a first electrode patterned on the main surface of the semiconductor substrate, and detects a material to be measured reaching the semiconductor substrate through the opening,
the first thin film covers an upper surface and a side surface of the first electrode, a bottom of the opening and at least a part of a side surface of the opening,
a surface of the first thin film at the bottom of the opening and at least the part of the side surface of the opening is exposed, and
the first thin film is a thin film electrically operating the sensor element by the material to be measured.

11. The semiconductor device according to claim 10,
wherein the first pattern of the third thin film is a pattern allowing a material with a desired shape in a test solution to transmit toward the first thin film.

12. The semiconductor device according to claim 10, further comprising:
a second thin film patterned between the third thin film and the second insulating film on the first region so as to cover an upper surface of the first electrode, and having etching selectivity to the first insulating film and the second insulating film,
wherein the opening is formed also in the second thin film.

13. The semiconductor device according to claim 12,
wherein the first insulating film is thinner than the second insulating film.

14. A manufacturing method of a semiconductor device comprising the steps of:
(a) forming a sensor element on a main surface of a semiconductor substrate;
(b) forming a first thin film on the main surface of the semiconductor substrate under a presence of the sensor element;
(c) forming a first insulating film on the main surface of the semiconductor substrate including the first thin film;
(d) forming a second thin film having etching selectivity to the first insulating film on the first insulating film, and patterning the second thin film on a first region of the main surface of the semiconductor substrate;
(e) forming a second insulating film having etching selectivity to the second thin film on the first insulating film including the second thin film;
(f) forming a first masking layer on the second insulating film and anisotropically dry etching the second insulating film on the first region by a first planer shape with using the first masking layer as a mask, thereby forming an opening reaching the second thin film;
(g) anisotropically dry etching the second thin film below the opening by the first planer shape with using the first masking layer as a mask, thereby expanding the opening so as to reach the first insulating film; and
(h) after the step (g), isotropically wet etching the first insulating film below the opening, thereby expanding the opening so as to reach the first thing film.

15. The manufacturing method of the semiconductor device according to claim 14,
wherein the step (a) includes a step of patterning a first electrode on the main surface of the semiconductor substrate,
the first electrode is included in the sensor element, and
in the step (h), a surface of the first thin film is exposed at a bottom of the opening and at least a part of a side surface of the opening.

16. The manufacturing method of the semiconductor device according to claim 14,
wherein the first insulating film is thinner than the second insulating film.

17. The manufacturing method of the semiconductor device according to claim 14,
wherein the first planer shape is a complicated planer shape.

18. A manufacturing method of a semiconductor device comprising the steps of:
(a) forming a first sensor element and a second sensor element on a main surface of a semiconductor substrate;
(b) forming a first thin film on the main surface of the semiconductor substrate under a presence of the first sensor element and the second sensor element;
(c) forming a first insulating film on the main surface of the semiconductor substrate including the first thin film,
(d) forming a second thin film having etching selectivity to the first insulating film on the first insulating film, and patterning the second thin film on a first region and a second region of the main surface of the semiconductor substrate,
(e) forming a second insulating film on the first insulating film including the second thin film, the second insulating film having etching selectivity to the second thin film and different film thicknesses on the first region and the second region;
(f) forming a first masking layer on the second insulating film and anisotropically dry etching the second insulating films on the first region and the second region respectively by a first planer shape with using the first masking layer as a mask, thereby forming openings reaching the second thin film in the first region and the second region, respectively;
(g) anisotropically dry etching the second thin film below the opening by the first planer shape with using the first masking layer as a mask, thereby expanding the opening so as to reach the first insulating film; and
(h) after the step (g), isotropically wet etching the first insulating film below the opening, thereby expanding the opening so as to reach the first thin film.

19. The manufacturing method of the semiconductor device according to claim 18,
wherein the step (a) includes a step of patterning a plurality of first electrodes on the main surface of the semiconductor substrate,
the plurality of first electrodes are included in the first sensor element and the second sensor element, and
in the step (h), a surface of the first thin film is exposed at a bottom of the opening and at least a part of a side surface of the opening.

20. The manufacturing method of the semiconductor device according to claim 18,
wherein the first insulating film is thinner than the second insulating film.

21. A manufacturing method of a semiconductor device comprising the steps of:
(a) forming a sensor element on a main surface of a semiconductor substrate;
(b) forming a first thin film on the main surface of the semiconductor substrate under a presence of the sensor element;
(c) forming a first insulating film on the main surface of the semiconductor substrate including the first thin film;
(d) forming a third thin film having etching selectivity to the first insulating film on the first insulating film, and patterning the third thin film on a first region of the main surface of the semiconductor substrate by a first pattern;
(e) forming a second thin film having etching selectivity to the first insulating film on the first insulating film including the third thin film, and patterning the second thin film on the first region;
(f) forming a second insulating film having etching selectivity to the second thin film on the first insulating film including the second thin film;
(g) forming a first masking layer on the second insulating film and anisotropically dry etching the second insulating film on the first region by a first planer shape with using the first masking layer as a mask, thereby forming an opening reaching the second thin film;
(h) anisotropically dry etching the second thin film below the opening by the first planer shape with using the first masking layer as a mask, thereby expanding the opening; and
(i) after the step (h), isotropically wet etching the first insulating film below the opening, thereby expanding the opening so as to reach the first thin film.

22. The manufacturing method of the semiconductor device according to claim 21,
wherein the step (a) includes a step of patterning a plurality of first electrodes on the main surface of the semiconductor substrate,
the plurality of first electrodes are included in the sensor element, and
in the step (i), a surface of the first thin film is exposed at a bottom of the opening and at least a part of a side surface of the opening.

23. The manufacturing method of the semiconductor device according to claim 21,
wherein the first insulating film is thinner than the second insulating film.
